(19) United States
(12) Patent Application Publication
(10) Pub. No.: US 2011/0223750 A1
(43) Pub. Date: Sep. 15, 2011

(54) METHOD FOR MANUFACTURING SEMICONDUCTOR DEVICE AND SEMICONDUCTOR MANUFACTURING APPARATUS

(76) Inventors: Hisataka HAYASHI, Yokohama-Shi (JP); Takeshi Kaminatsui, Yokohama-Shi (JP); Akio Ui, Tokyo (JP)

(21) Appl. No.: 13/043,017

(22) Filed: Mar. 8, 2011

(30) Foreign Application Priority Data
Mar. 9, 2010 (JP) 2010-52030
Feb. 2, 2011 (JP) 2011-20763

(51) Int. Cl. H01L 21/265; C23C 16/515; H01L 21/3065; H01L 21/31

(52) U.S. Cl. 438/513; 118/704; 118/723 MP; 156/345.28; 156/345.38; 438/710; 438/758; 257/E21.218; 257/E21.24; 257/E21.211; 257/E21.334

(57) ABSTRACT

According to an embodiment, a method for manufacturing a semiconductor device is disclosed. The method includes: arranging a semiconductor substrate on a first electrode out of first and second electrodes arranged to be opposed to each other in a vacuum container; applying negative first pulse voltage and radio-frequency voltage to the first electrode, the negative first pulse voltage being superimposed with the radio-frequency voltage; applying negative second pulse voltage to the second electrode in an off period of the first pulse voltage; and processing the semiconductor substrate or a member on the semiconductor substrate by plasma formed between the first and second electrodes.

### CROSS REFERENCE TO RELATED APPLICATIONS

This application is based upon and claims the benefit of priority from the prior Japanese Patent Application No. 2010-52030 filed on Mar. 9, 2010 and No. 2011-20763 filed on Feb. 2, 2011, the entire contents of which are incorporated herein by reference.

### FIELD

Embodiments described herein relate generally to a method for manufacturing a semiconductor device in which a semiconductor substrate or a member on the semiconductor substrate is processed by plasma, and a semiconductor manufacturing apparatus.

### BACKGROUND

Recently, a trend toward development of a high-performance, high-integration, and ultra-fine semiconductor device has been rapidly increased. To develop a highly integrated semiconductor device, an ultra-fine process technique, an epitaxial growth technique, a packaging technique, etc. need to be improved. Among other things, the ultra-fine process technique is especially important, and improvements in process accuracy such as a high aspect ratio and reduction in the minimum line width are strongly required.

As one of such ultra-fine process techniques for the semiconductor device, Reactive Ion Etching (RIE) enabling an anisotropic ultra-fine process at a high etching rate is known. Generally in the RIE, a pair of electrodes is arranged with a predetermined distance to be opposed to each other in a chamber enabling atmospheric control, the substrate is held on one electrode, and radio-frequency power (RF power) is supplied to the electrodes to generate plasma between the electrodes.

RIE utilizes a combined effect of physical etching (sputtering) and chemical etching by active neutral radicals. In the physical etching, positive ions in the plasma are accelerated by a potential difference between self-bias voltage generated in the substrate and plasma potential, and are incident and sputtered onto the substrate.

Since the plasma potential is relatively smaller than the self-bias voltage, energy control of the positive ions incident in the substrate is done by control of the self-bias voltage. The electrode potential periodically changes in response to the RF voltage, and thus the ion energy periodically changes as well. It is known that the ion energy is dispersed depending on the frequency of the RF voltage, and that the lower the frequency of the RF voltage is, the more the ion energy is dispersed. When the ion energy is dispersed, high-energy positive ions may induce shoulder cutting to degrade the process shape while low-energy positive ions may not contribute to the substrate process or may degrade the process shape along with deterioration of anisotropy.

Under such circumstances, a technique to use two or more kinds of RF power having different frequencies from each other: RF power to generate and maintain plasma and RF power to control ion energy, is proposed (for example, refer to Japanese Patent Application Laid-Open No. 2003-234331).

However, in such a conventional technique, dispersion of the ion energy caused by the lower frequency is significant, and it is difficult to sufficiently narrow the dispersion down to a range required for improvement in the process accuracy. Also, the dispersion of the ion energy can be reduced by heightening the lower frequency, but this causes a problem of difficulty in obtaining desired ion energy.

Also, a technique to restrict dispersion of ion energy by superimposing negative DC pulse voltage with radio-frequency power having frequency of 50 MHz or higher and applying it to a wafer-arranging electrode is proposed (for example, refer to Japanese Patent Application Laid-Open No. 2008-85288).

In this technique, since the waveform of the voltage applied to the wafer-arranging electrode is a square wave, not a sine wave, the ion energy distribution is narrowed, and the process shape is controlled with use of an arbitrarily controlled energy band. Controlling the energy distribution in high accuracy in such a manner obtains a high-accuracy process. On the other hand, even in a case where the ion energy is controlled in high accuracy, positive ions are accelerated and are vertically incident in a specimen to reach a bottom surface of an ultra-fine pattern while electrons are not accelerated and are isotropically incident in the specimen thus to fail in reaching the bottom surface of the ultra-fine pattern because they are shaded by a mask (electron shading). This brings about a phenomenon in which a side surface of the ultra-fine pattern is charged up negatively while the bottom surface is charged up positively. Such charge-ups induce degradation of the process shape due to ion deviation, etching stop, and damage of the device due to charged voltage.

### BRIEF DESCRIPTION OF THE DRAWINGS

FIG. 1 is a schematic diagram of a plasma processing apparatus as a semiconductor manufacturing apparatus according to a first embodiment of the present invention.

FIG. 2 is a diagram showing voltage waveforms of the plasma processing apparatus according to a first embodiment.

FIG. 3(a) is a diagram showing positional relationship between each electrode and the semiconductor wafer, and FIG. 3(b) is a diagram showing potential distribution between the electrodes.

FIG. 4(a) is a cross-sectional view showing a charge-up state of a fine-width groove, and FIGS. 4(b) and 4(c) are cross-sectional views showing a state of alleviating the charge-up at the bottom portion of the fine-width groove.

FIG. 5 is a schematic diagram of a plasma processing apparatus according to a second embodiment of the present invention.

FIG. 6 is a diagram showing voltage waveforms of a plasma processing apparatus according to a third embodiment of the present invention.

### DETAILED DESCRIPTION

According to an embodiment, a method for manufacturing a semiconductor device is disclosed. The method includes: arranging a semiconductor substrate on a first electrode out of first and second electrodes arranged to be opposed to each other in a vacuum container; applying negative first pulse voltage and radio-frequency voltage to the first electrode, the negative first pulse voltage being superimposed with the radio-frequency voltage; applying negative second pulse voltage to the second electrode in an off period of the first pulse voltage; and processing the semiconductor substrate or a member on the semiconductor substrate by plasma formed between the first and second electrodes.

### First Embodiment

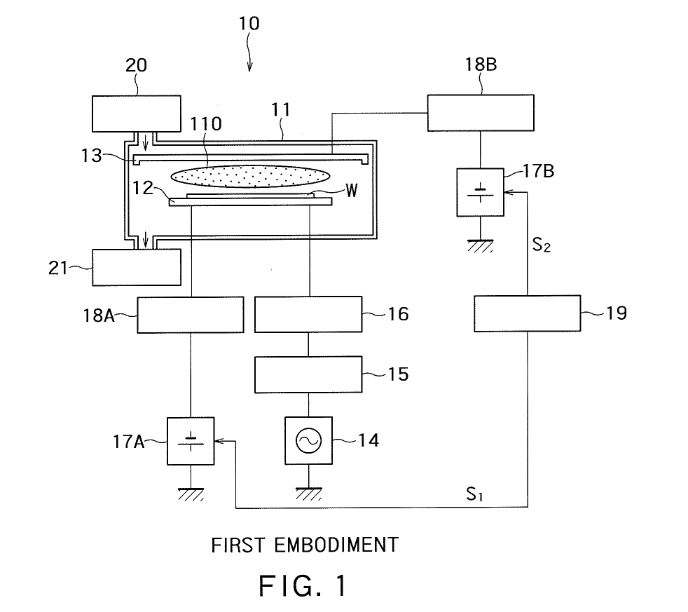

FIG. 1 is a schematic diagram of a plasma processing apparatus as a semiconductor manufacturing apparatus according to a first embodiment of the present invention.

This plasma processing apparatus 10 is a so-to-speak parallel flat plate type plasma processing apparatus having a chamber (vacuum container) 11 that can keep the inside vacuum, having a wafer-arranging electrode (first electrode) 12 and a counter electrode (second electrode) 13 arranged in the chamber 11 so as to be opposed to each other, and processing a semiconductor wafer (semiconductor substrate) W held on the wafer-arranging electrode 12 or a member on the semiconductor wafer W such as an insulating film, a semiconductor film, or the like by plasma 110 generated between the electrodes 12, 13. It is noted that “processing” includes not only a process by etching but also film formation, ion injection, surface modification, etc.

The plasma processing apparatus 10 also includes a radio-frequency power supply 14 applying radio-frequency voltage to the wafer-arranging electrode 12 via a matching unit 15 and a high-pass filter (HPF) 16, a first DC pulse power supply 17A applying negative first DC pulse voltage (first pulse voltage) V₁ to the wafer-arranging electrode 12 via a low-pass filter (LPF) 18A, a second DC pulse power supply 17B applying negative second DC pulse voltage (second pulse voltage) V₂ to the counter electrode 13 via a low-pass filter (LPF) 18B, a control circuit 19 outputting first and second trigger signals S₁, S₂ to the first and second DC pulse power supplies 17A, 17B, a gas supplying unit 20 supplying the chamber 11 with gas required for processing of the semiconductor wafer W, and a gas exhausting unit 21 exhausting gas from the chamber 11 by a vacuum pump or the like.

The radio-frequency power supply 14 is configured to generate radio-frequency voltage of 50 MHz to 150 MHz, such as radio-frequency voltage (RF voltage) of 100 MHz, 40 V, and apply it to the wafer-arranging electrode 12. By applying the radio-frequency voltage to the wafer-arranging electrode 12, the plasma 110 is generated between the electrodes 12, 13, and the plasma density is determined by the frequency of the radio-frequency voltage.

The first DC pulse power supply 17A is configured to generate negative first DC pulse voltage V₁ of −100 to −2500 V having a frequency of 500 kHz to 3 MHz, such as voltage of 1 MHz, −500 V, superimpose this first DC pulse voltage V₁ with the radio-frequency voltage from the radio-frequency power supply 14, and apply it to the wafer-arranging electrode 12. By superimposing the first DC pulse voltage V₁ with the radio-frequency voltage, energy of positive ions in the plasma 110 incident in the semiconductor wafer W can be controlled.

The second DC pulse power supply 17B is configured to generate negative second DC pulse voltage V₂ of −100 to −1000 V having a frequency of 500 kHz to 3 MHz, such as voltage of 1 MHz, −300 V, and apply it to the counter electrode 13. Etching by irradiating the semiconductor wafer W with the positive ions in the plasma 110 may cause a bottom portion of a pattern to be charged up positively in some cases. By controlling the pulse width, voltage value, etc. of the second DC pulse voltage V₂, a potential difference occurring in ion sheath between the plasma 110 and the counter electrode 13 can be controlled arbitrarily, which alleviates the charge-up at the bottom portion of the pattern by the positive ions. Details of the alleviation of the charge-up will be described in an operation of the present embodiment.

At the timing of applying the second DC pulse voltage V₂, the value of the voltage has only to be one to make the potential of the wafer-arranging electrode 12 higher than the potential of the counter electrode 13. Negative second pulse voltage V₂ may be applied to the counter electrode 13 while positive pulse voltage may be applied to the wafer-arranging electrode 12. For example, −200 V may be applied to the counter electrode 13 while +100 V may be applied to the wafer-arranging electrode 12.

The pulse width and the voltage value of the second pulse voltage V₂ may be determined in accordance with, e.g., the aspect ratio in a manner in which the pulse width is larger, or the voltage value is smaller, when the aspect ratio is larger. For example, when the aspect ratio is 7, the pulse width of the second pulse voltage V₂ may be set to 200 ns while the voltage value may be set to −300 V. Also, for example, when the aspect ratio is 10, the pulse width may be set to 300 ns while the voltage value may be set to −500 V.

The matching unit 15 ensures impedance matching between the radio-frequency power supply 14 and the plasma 110.

The high-pass filter 16 lets the radio-frequency voltage from the radio-frequency power supply 14 pass therethrough and blocks the flow of the pulse voltage from the first and second DC pulse power supplies 17A, 17B into the radio-frequency power supply 14.

The low-pass filters 18A, 18B let the DC pulse voltage from the DC pulse power supplies 17A, 17B pass therethrough and block the flow of the radio-frequency voltage from the radio-frequency power supply 14 into the DC pulse power supplies 17A, 17B.

The control circuit 19 is configured to have a CPU, a memory having stored therein control programs of the CPU and data, an interface circuit, etc. Also, the control circuit 19 outputs the first trigger signal S₁ to the first DC pulse power supply 17A to control the output timing of the first DC pulse voltage V₁ and outputs the second trigger signal S₂ to the second DC pulse power supply 17B to control the output timing of the second DC pulse voltage V₂ so that, in an off period of the first DC pulse voltage V₁, the second DC pulse voltage V₂ having a shorter pulse width than the off period may be applied to the counter electrode 13.

The gas supplying unit 20 supplies the chamber 11 with gas required for processing of the semiconductor wafer W such as CF₄, C₄F₈, Cl₂, HBr, O₂, Ar, N₂, or H₂.

### Operation of Present Embodiment

Next, an operation of the plasma processing apparatus 10 according to the present embodiment will be described with reference to the drawings. The operation of processing the semiconductor wafer W or an insulator on the semiconductor wafer W will be described below.

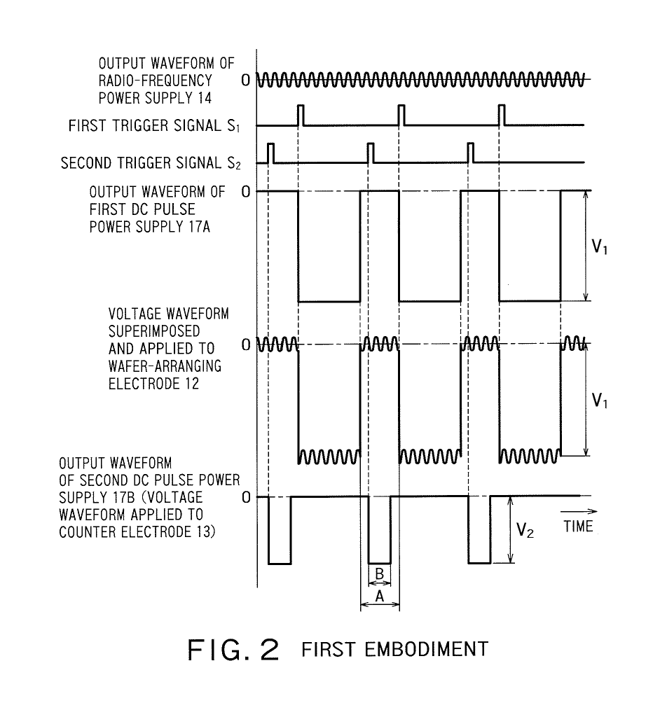

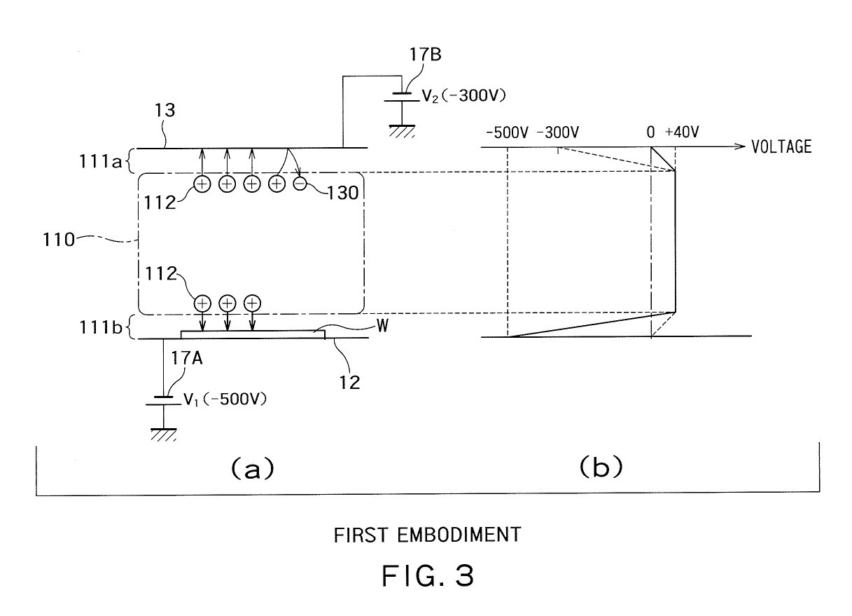

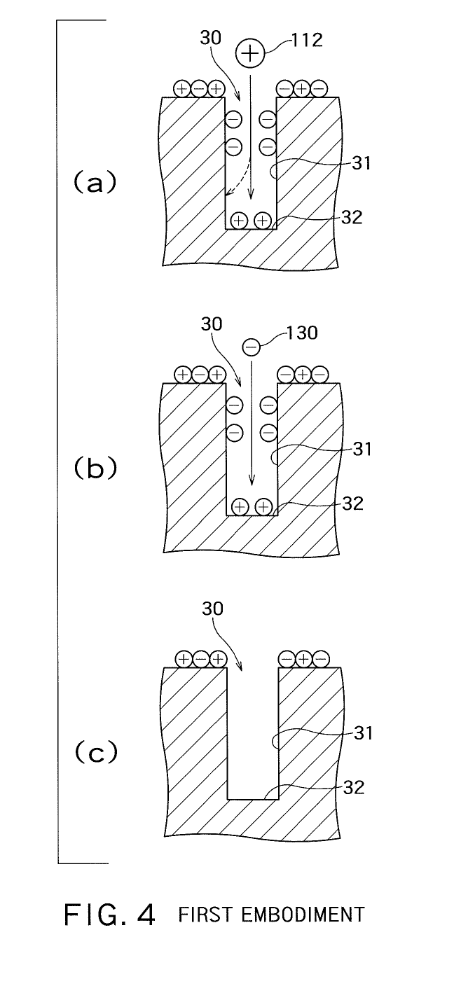

FIG. 2 shows voltage waveforms. FIG. 3(a) shows positional relationship between each electrode and the semiconductor wafer, and FIG. 3(b) shows potential distribution between the electrodes. FIG. 4(a) is a cross-sectional view showing a charge-up state of a fine-width groove, and FIGS. 4(b) and 4(c) are cross-sectional views showing a state of alleviating the charge-up at the bottom portion of the fine-width groove.

Etching gas such as C₄F₈ required for processing of the semiconductor wafer W or the insulator on the semiconductor wafer W is supplied from the gas supplying unit 20 to the chamber 11, and the interior of the chamber 11 is exhausted by the gas exhausting unit 21 to keep the interior of the chamber 11 at a predetermined degree of vacuum (e.g., several Pa).

Subsequently, the radio-frequency power supply 14 applies radio-frequency voltage to the wafer-arranging electrode 12. The control circuit 19 outputs trigger signals S₁, S₂ so that a pulse width B of the second DC pulse voltage V₂ may be shorter than an off period A of the first DC pulse voltage V₁ as shown in FIG. 2. The first DC pulse power supply 17A applies negative first DC pulse voltage V₁, such as voltage of 1 MHz, −500 V, to the wafer-arranging electrode 12 in sync with the first trigger signal S₁ from the control circuit 19. The second DC pulse power supply 17B applies negative second DC pulse voltage V₂, such as voltage of 1 MHz, −300 V, to the counter electrode 13 in sync with the second trigger signal S₂ from the control circuit 19. To the wafer-arranging electrode 12, voltage made by superimposing the first DC pulse voltage V₁ with the radio-frequency voltage is applied.

### (1) Timing of Applying the First DC Pulse Voltage V₁ to the Wafer-Arranging Electrode 12

As a result of applying the radio-frequency voltage and the first DC pulse voltage V₁ to the wafer-arranging electrode 12, the plasma 110 is formed between the wafer-arranging electrode 12 and the counter electrode 13, and the gas is ionized.

In the vicinities of the surfaces of the wafer-arranging electrode 12 and the counter electrode 13, ion sheaths (space charge layers) 111a, 111b in which positive ions are aggregated are formed, respectively.

At the timing of applying the first DC pulse voltage V₁ to the wafer-arranging electrode 12, in the solid line (potential distribution including 0 V, +40 V, and −500 V) in FIG. 3(b), positive ions 112 in the plasma 110 are accelerated by a potential difference in the ion sheath 111b on the side of the wafer-arranging electrode 12 and are sputtered onto the semiconductor wafer W or the insulator on the semiconductor wafer W to cause etching.

In a case of forming a groove or a hole in the insulator, such as an oxide film or a nitride film, on the semiconductor wafer W, at the timing of applying the first DC pulse voltage to the wafer-arranging electrode 12, a side surface 31 of a fine-width groove 30 may be charged up negatively while a bottom portion 32 may be charged up positively due to insufficient electrons in some cases as shown in FIG. 4(a). When such charge-ups occur, the positive ions 112 incident in the groove 30 will be deviated or decelerated, which induces degradation of the process shape, etching stop, damage of the device due to charged voltage, etc.

### (2) Timing of Applying the Second DC Pulse Voltage V₂ to the Counter Electrode 13

At the timing of applying the second DC pulse voltage V₂ to the counter electrode 13, in the dashed line (potential distribution including −300 V, +40 V, and 0 V) in FIG. 3(b), the positive ions 112 are accelerated by a potential difference in the ion sheath 111a on the side of the counter electrode 13 and are sputtered onto the counter electrode 13, and secondary electrons 130 are generated from the counter electrode 13. After the secondary electrons 130 are accelerated by the potential difference in the ion sheath 111a on the side of the counter electrode 13, they pass through the plasma 110 with a potential of +40 V, move toward the semiconductor wafer W anisotropically, and are incident in the bottom portion 32 of the groove 30 on the surface of the insulator on the semiconductor wafer W as shown in FIG. 4(b).

The incidence of the electrons 130 in the bottom portion 32 of the groove 30 as shown in FIG. 4(b) alleviates the negative charge-up at the side surface 31 of the groove 30 and the positive charge-up at the bottom portion 32 as shown in FIG. 4(c), which restricts the degradation of the process shape, etching stop, damage of the device due to charged voltage, etc. Meanwhile, the charge-up at the bottom portion 32 by the positive ions can be alleviated not only in the case where the entire groove 30 is an insulator but also in the case where the bottom portion 32 is an insulator. It is noted that “alleviation of a charge-up by positive ions” includes elimination of the positive charge-up as well as its reduction.

A recess such as an element separation groove is formed in a case of processing the semiconductor wafer W by the above plasma processing apparatus 10, and a recess such as a contact hole is formed in a case of processing the insulator on the semiconductor wafer W.

### Effect of First Embodiment

According to the first embodiment described above, the positive charge-up occurring at the bottom portion of the recess pattern such as a groove or a hole by etching with use of positive ions can be alleviated, which leads to improvement in the process accuracy.

Also, applying the second pulse voltage in the off period

A of the first pulse voltage avoids deceleration of the electrons more than in the case of applying the second pulse voltage in the on period of the first pulse voltage, which enables the electrons to be supplied efficiently to the bottom portion of the pattern. Meanwhile, the pulse width B of the second DC pulse voltage V₂ may be equivalent to or longer than the off period A of the first DC pulse voltage V₁.

Further, since the ion energy distribution is narrowed by superimposing the pulse voltage with the radio-frequency voltage, such control of the ion energy can restrict degradation of the process shape due to shoulder cutting.

### Second Embodiment

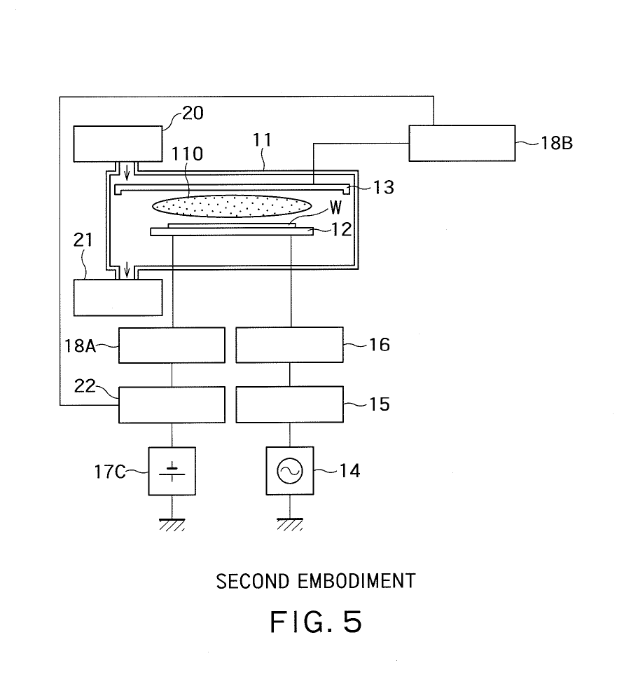

FIG. 5 is a schematic diagram of a plasma processing apparatus according to a second embodiment of the present invention.

In the second embodiment, a single DC pulse power supply 17C is used instead of the first and second DC pulse power supplies 17A, 17B of the first embodiment.

A plasma processing apparatus 1 according to the second embodiment includes the chamber 11, the wafer-arranging electrode 12, the counter electrode 13, the radio-frequency power supply 14, the matching unit 15 and high-pass filter (HPF) 16, and the gas supplying unit 20 and gas exhausting unit 21 in a similar manner to that of the first embodiment, and additionally includes the DC pulse power supply 17C outputting negative first and second DC pulse voltage and a switching circuit 22 performing switching control so as to apply the negative first DC pulse voltage from the DC pulse power supply 17C to the wafer-arranging electrode 12 via the low-pass filter (LPF) 18A or apply the negative second DC pulse voltage from the DC pulse power supply 17C to the counter electrode 13 via the low-pass filter (LPF) 18B.

The DC pulse power supply 17C is configured to generate negative first or second DC pulse voltage of −100 to −2500 V having a frequency of 500 kHz to 3 MHz, such as voltage of 1 MHz, −500 V, and apply it to the wafer-arranging electrode 12 or the counter electrode 13 by the switching control of the switching circuit 22.

The switching circuit 22 performs switching control so that the timings of applying the DC pulse voltage to the wafer-arranging electrode 12 and the counter electrode 13 may be the same as those in the first embodiment. However, in the present embodiment, the DC pulse voltage to be applied to the counter electrode 13 is in the same value as that of the DC pulse voltage to be applied to the wafer-arranging electrode 12.

According to the present embodiment, the DC pulse power supply for plasma formation and the DC pulse power supply for charge-up alleviation can be unified.

### Third Embodiment

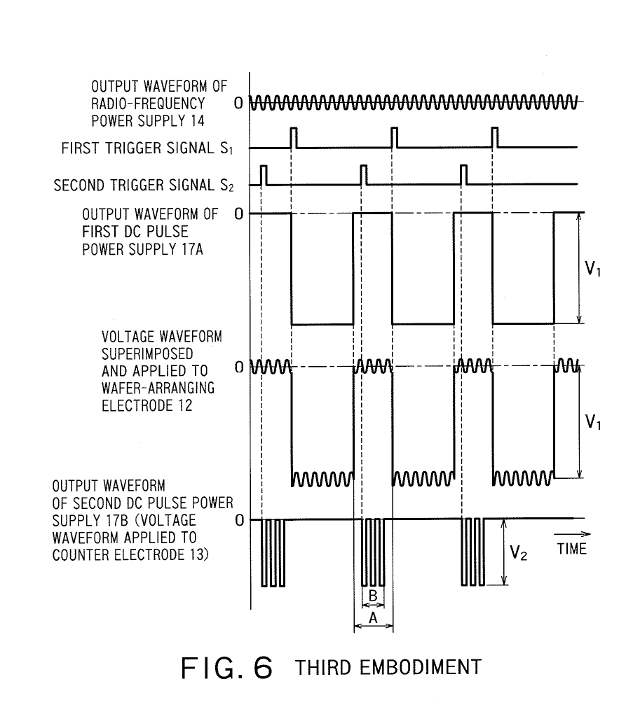

FIG. 6 shows voltage waveforms of a plasma processing apparatus according to a third embodiment of the present invention. The present embodiment is configured in the same manner as that of the first embodiment except that the second DC pulse power supply 17B of the first embodiment is adapted to output negative DC pulse voltage having a burst waveform.

According to the third embodiment, the charge-up on the surface of the semiconductor wafer W by positive ions can be alleviated in accordance with a period in which the burst-waveform voltage is applied to the counter electrode 13. Accordingly, the secondary electrons are emitted from the counter electrode 13 efficiently, which causes improvement in reduction of the charge-up of the semiconductor wafer W. Also, the amount of secondary electrons to be generated is decreased more than in the case of the first and second embodiments that do not use burst-waveform voltage, which can lessen consumption of the counter electrode 13.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A method for manufacturing a semiconductor device, comprising:
arranging a semiconductor substrate on a first electrode out of first and second electrodes arranged to be opposed to each other in a vacuum container;
applying negative first pulse voltage and radio-frequency voltage to the first electrode, the negative first pulse voltage being superimposed with the radio-frequency voltage;
applying negative second pulse voltage to the second electrode in an off period of the first pulse voltage; and
processing the semiconductor substrate or a member on the semiconductor substrate by plasma formed between the first and second electrodes.

2. The method for manufacturing a semiconductor device according to claim 1, wherein the applying the second pulse voltage comprises applying the second pulse voltage having a shorter pulse width than the off period of the first pulse voltage.

3. The method for manufacturing a semiconductor device according to claim 1, wherein the applying the second pulse voltage comprises applying the second pulse voltage having a burst waveform.

4. The method for manufacturing a semiconductor device according to claim 1, wherein the applying the second pulse voltage comprises applying the negative second pulse voltage to the second electrode and applying positive pulse voltage to the first electrode.

5. The method for manufacturing a semiconductor device according to claim 1, wherein the first pulse voltage has the same value as that of the second pulse voltage.

6. The method for manufacturing a semiconductor device according to claim 1, wherein the applying the second pulse voltage comprises applying the second pulse voltage having a longer pulse width than the off period of the first pulse voltage.

7. The method for manufacturing a semiconductor device according to claim 1, wherein frequency of the first pulse voltage is the same as frequency of the second pulse voltage.

8. The method for manufacturing a semiconductor device according to claim 1, wherein frequency of the radio-frequency voltage is 50 MHz to 150 MHz.

9. The method for manufacturing a semiconductor device according to claim 1, wherein the first pulse voltage is −100 V to −2500 V, and frequency of the first pulse voltage is 500 kHz to 3 MHz.

10. The method for manufacturing a semiconductor device according to claim 1, wherein the second pulse voltage is −100 V to −1000 V, and frequency of the second pulse voltage is 500 kHz to 3 MHz.

11. The method for manufacturing a semiconductor device according to claim 1, wherein the processing the semiconductor substrate or the member on the semiconductor substrate comprises performing at least any of such processing items as a process by etching, film formation, ion injection, and surface modification.

12. A semiconductor manufacturing apparatus comprising:
a vacuum container;
a first electrode provided in the vacuum container, a semiconductor substrate to be processed being arranged on the first electrode;
a second electrode provided in the vacuum container to be opposed to the first electrode;
a radio-frequency power supply applying radio-frequency voltage to the first electrode;
a first pulse power supply applying negative first pulse voltage to the first electrode so as to be superimposed with the radio-frequency voltage to process the semiconductor substrate or a member on the semiconductor substrate by plasma formed between the first and second electrodes; and
a second pulse power supply applying negative second pulse voltage to the second electrode in an off period of the first pulse voltage.

13. The semiconductor manufacturing apparatus according to claim 12, wherein the second pulse power supply applies the second pulse voltage having a shorter pulse width than the off period of the first pulse voltage.

14. The semiconductor manufacturing apparatus according to claim 12, wherein the second pulse power supply applies the second pulse voltage having a burst waveform.

15. The semiconductor manufacturing apparatus according to claim 12, wherein, when the second pulse power supply applies the negative second pulse voltage to the second electrode, the first pulse power supply applies positive pulse voltage to the first electrode.

16. The semiconductor manufacturing apparatus according to claim 12, wherein the second pulse power supply applies the second pulse voltage having a longer pulse width than the off period of the first pulse voltage.

17. The semiconductor manufacturing apparatus according to claim 12, further comprising:
a high-pass filter connected between the radio-frequency power supply and the first electrode, the high-pass filter passing the radio-frequency voltage to the first electrode and blocking the first pulse voltage and the second pulse voltage;
a first low-pass filter connected between the first pulse power supply and the first electrode, the first low-pass filter passing the first pulse voltage to the first electrode and blocking the radio-frequency voltage; and
a second low-pass filter connected between the second pulse power supply and the second electrode, the second low-pass filter passing the second pulse voltage to the second electrode and blocking the radio-frequency voltage.

18. A semiconductor manufacturing apparatus comprising:
a vacuum container;
a first electrode provided in the vacuum container, a semiconductor substrate to be processed being arranged on the first electrode;
a second electrode provided in the vacuum container to be opposed to the first electrode;
a radio-frequency power supply applying radio-frequency voltage to the first electrode;
a pulse power supply outputting negative first pulse voltage and negative second pulse voltage, the first pulse voltage having the same value as that of the second pulse voltage; and
a switching circuit performing switching control so as to apply the first pulse voltage to the first electrode so as to be superimposed with the radio-frequency voltage to process the semiconductor substrate or a member on the semiconductor substrate by plasma formed between the first and second electrodes, and so as to apply the second pulse voltage to the second electrode in an off period of the first pulse voltage.

19. The semiconductor manufacturing apparatus according to claim 18, further comprising:
a high-pass filter connected between the radio-frequency power supply and the first electrode, the high-pass filter passing the radio-frequency voltage to the first electrode and blocking the first pulse voltage and the second pulse voltage;
a first low-pass filter connected between the switching circuit and the first electrode, the first low-pass filter passing the first pulse voltage to the first electrode and blocking the radio-frequency voltage; and
a second low-pass filter connected between the switching circuit and the second electrode, the second low-pass filter passing the second pulse voltage to the second electrode and blocking the radio-frequency voltage.
